(19) United States
(12) Patent Application Publication
(10) Pub. No.: US 2019/0086742 A1
(43) Pub. Date: Mar. 21, 2019

(54) DISPLAY PANEL AND DISPLAY DEVICE

(71) Applicants: BOE Technology Group Co., Ltd., Beijing (CN); BEIJING BOE DISPLAY TECHNOLOGY CO., LTD., Beijing (CN)

(72) Inventors: Haiqin Huang, Beijing (CN); Xiaopeng Cui, Beijing (CN)

(21) Appl. No.: 16/011,874

(22) Filed: Jun. 19, 2018

(30) Foreign Application Priority Data
Sep. 20, 2017 (CN) 201721218558.2

(51) Int. Cl. G02F 1/1343; H01L 27/12; G02F 1/1335; G02F 1/1337

(52) U.S. Cl. CPC G02F 1/134309; H01L 27/1214; G02F 2201/123; G02F 1/1337; G02F 2201/121; G02F 1/133512

(57) ABSTRACT

Embodiments of the disclosure relate to a technical field of liquid crystal display technology, and disclose a display panel and a display device, the display panel including: an array substrate; and a first metal layer and pixel electrodes, both being formed on the array substrate, the first metal layer forming data lines, wherein the display panel further comprises a plurality of first electrodes which are arranged to be spaced apart from one another and provided between the first metal layer and a layer in which the pixel electrodes are located.

### CROSS-REFERENCE TO RELATED DISCLOSURE

The present disclosure claims the benefit of Chinese Patent Application Disclosure No. 201721218558.2 filed on Sep. 20, 2017 in the State Intellectual Property Office of China, the whole disclosure of which is incorporated herein by reference.

### BACKGROUND OF THE DISCLOSURE

### Field of the Disclosure

Embodiments of the present disclosure relate to the technical field of liquid crystal display technology, and especially to a display panel and a display device.

### Description of the Related Art

In the technical field of liquid crystal display technology, as TFT-LCD (i.e., thin-film transistor liquid crystal display) is widely used, various novel technologies which may enhance display effect are gradually applied to TFT-LCD. By way of example, in order to decrease power consumption, a Z-inversion in combination with a column inversion may be applied at present, i.e., a novel pixel structure in a form of Z-inversion, which cooperates with signal column(s) of Data-Lines arranged in a form of column inversion, is applied, so as to ensure the display effect and to further decrease power consumption of TFT-LCD.

At present, in relevant TFT-LCD using Z-version in combination with column version, since there may be some process fluctuations such as alignment deviation and the like between data lines and pixel electrodes, then coupling capacitors (abbreviated as ‘Cpd’) created between data lines an pixel electrodes may deflect, and in turn influences of the ‘Cpd’ capacitors therebetween on pixel voltages of even rows and odd rows may differ from each other; and under the action of the influenced pixel voltages of the even rows and odd rows, a display panel of the TFT-LCD type may macroscopically present horizontal trace-mura in which both bright and dark stripes are arranged alternately.

### SUMMARY OF THE DISCLOSURE

The embodiments of the present disclosure have been made to overcome or alleviate at least one aspect of the above mentioned disadvantages and/or shortcomings in the prior art, by providing a display panel and a display device.

Following technical solutions are adopted in exemplary embodiments of the disclosure for achieving the above desired technical purposes.

According to an aspect of the exemplary embodiment of the present disclosure, there is provided a display panel, comprising: an array substrate; and a first metal layer and pixel electrodes, both being formed on the array substrate, the first metal layer forming data lines; and the display panel further comprises a plurality of first electrodes which are arranged to be spaced apart from one another and provided between the first metal layer and a layer in which the pixel electrodes are located.

In an embodiment of the disclosure, the plurality of first electrodes may be transparent electrodes.

In an embodiment of the disclosure, the transparent electrodes are formed by transparent ITO material.

In an embodiment of the disclosure, the display panel further comprises a common electrode; and in response to the common electrode being arranged adjacent to and abutting against the array substrate, the pixel electrodes are arranged away from the array substrate.

In an embodiment of the disclosure, the display panel further comprises a common electrode; and in response to the common electrode being arranged away from the array substrate, the pixel electrodes are arranged adjacent to and abutting against the array substrate.

In an embodiment of the disclosure, the plurality of first electrodes may be connected with the common electrode through via-holes.

In an embodiment of the disclosure, at least a portion of an orthogonal projection of each of the plurality of first electrodes on the first metal layer does not overlap with respective one of the data lines.

In an embodiment of the disclosure, at least a portion of an orthogonal projection of each of the plurality of first electrodes on the first metal layer does not overlap with respective one of the data lines.

In an embodiment of the disclosure, the plurality of first electrodes may be electrically connected to an external common voltage.

In an embodiment of the disclosure, an orthogonal projection of the plurality of first electrodes on the layer in which the pixel electrodes are located does not overlap with the pixel electrodes.

In an embodiment of the disclosure, an orthogonal projection of the plurality of first electrodes on the layer in which the common electrode is located at least partially overlaps with the common electrode.

In an embodiment of the disclosure, the display panel further comprises an alignment substrate provided opposite to the array substrate, with a black matrix being formed on the alignment substrate, wherein in response to the pixel electrodes being provided away from the array substrate, an orthogonal projection of the plurality of first electrodes on a layer in which the black matrix is located falls within an extent of the black matrix.

According to another aspect of the exemplary embodiment of the present disclosure, there is provided a display device, comprising: the display panel as above; and a housing receiving the display panel.

### BRIEF DESCRIPTION OF THE DRAWINGS

The above and other features and advantages of the present disclosure will become more apparent and a more comprehensive understanding of the present disclosure can be obtained, by describing in detail exemplary embodiments thereof with reference to the accompanying drawings, in which:

FIG. 1 illustrates a schematic structural view of a display panel according to an embodiment of the disclosure;

FIG. 2 illustrates a schematic structural view of a display panel according to another embodiment of the disclosure;

FIG. 3 illustrates a schematic structural view of the display panel as illustrated in FIG. 1, with one of first electrodes being illustrated to connect with a common electrode through a respective via-hole;

FIG. 4 illustrates a schematic structural view of the display panel as illustrated in FIG. 2, with one of first electrodes being illustrated to connect with a common electrode through a respective via-hole.

### DETAILED DESCRIPTION OF EMBODIMENTS OF THE DISCLOSURE

Exemplary embodiments of the present disclosure will be described hereinafter in detail with reference to the attached drawings, wherein the like reference numerals refer to the like elements. The present disclosure may, however, be embodied in many different forms, and thus the detailed description of the embodiment of the disclosure in view of attached drawings should not be construed as being limited to the embodiment set forth herein; rather, these embodiments are provided so that the present disclosure will be thorough and complete, and will fully convey the general concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

Respective dimension and shape of each component in the drawings are only intended to exemplarily illustrate the contents of the disclosure, rather than to demonstrate the practical dimension or proportion of components of a display panel and a display device.

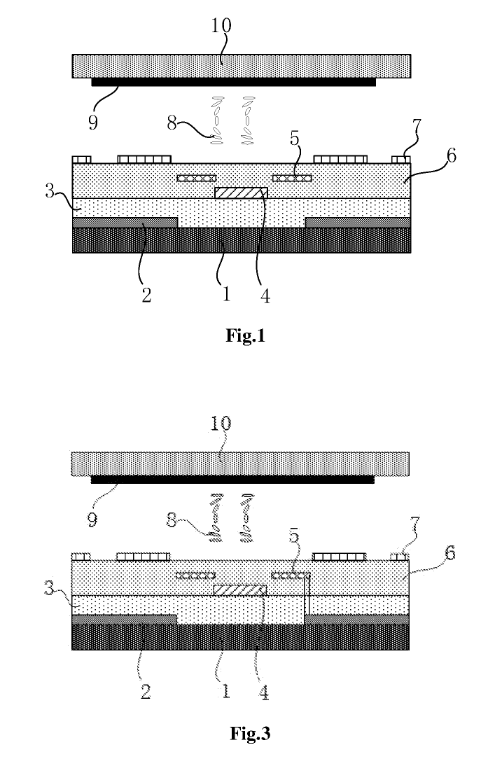

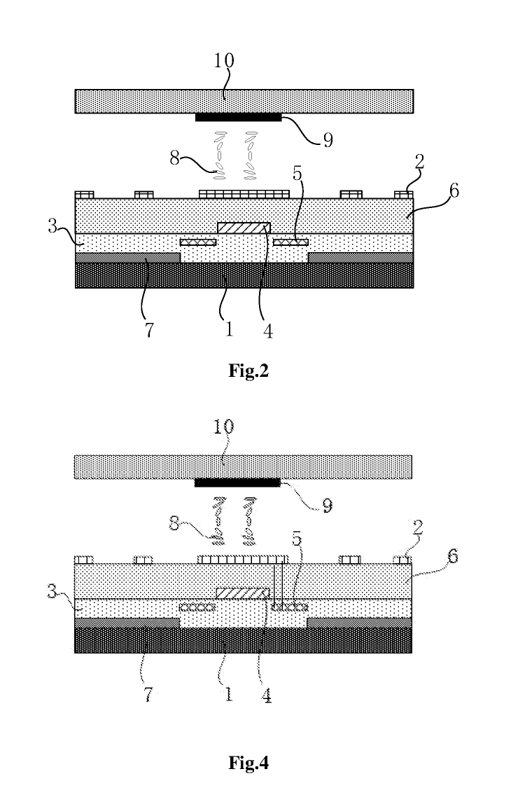

According to a general technical concept of embodiments of the present disclosure, as illustrated in FIG. 1 and FIG. 2, in a first aspect of the embodiments of the disclosure, there is provided a display panel, comprising: an array substrate 1; and a first metal layer and pixel electrodes 7, both being formed on the array substrate 1, the first metal layer forming data lines 4. The display panel further comprises a plurality of first electrodes 5 provided between the first metal layer and a layer in which the pixel electrodes 7 are located

In above display panel, since the plurality of first electrodes 5 are provided between the first metal layer and the layer in which the pixel electrodes 7 are located, such that a shielding effect may be applied on the coupling capacitors created between the data lines 4 and the pixel electrodes 7, decreasing (or even eliminating) the coupling capacitances between the data lines 4 and the pixel electrodes 7, in turn decreasing (or even eliminating) an influence on pixel voltages applied by the coupling capacitors created between the data lines 4 and the pixel electrodes 7, and resulting in a decreased difference between pixel voltages of even rows and odd rows; and therefore, a horizontal trace-mura phenomenon, which is caused by the difference between pixel voltages of even rows and odd rows and macroscopically presented as both bright and dark stripes arranged alternately on the display panel, may further be mitigated so as to ensure an normal display effect of the display panel.

Therefore, the aforementioned display panel may decrease an occurrence of the bright and dark stripes arranged alternately so as to improve display quality.

Based on above display panel which may decrease the occurrence of the bright and dark stripes arranged alternately and in turn improve display quality, in order to avoid any influence on pixel aperture ratio, then, in an embodiment of the disclosure, the plurality of first electrodes are transparent electrodes.

In above display panel, the plurality of first electrodes 5 are for example metal electrodes; and the plurality of first electrodes 5 may also for example be transparent electrodes and thus has no influence on the pixel aperture ratio. Therefore, by using transparent electrodes as the plurality of first electrodes in the display panel, a problem of poor display effect resulting from the bright and dark stripes being arranged alternately may be solved macroscopically, without any influence on the pixel aperture ratio, simultaneously.

Specifically, the transparent electrodes are for example formed by transparent ITO (Indium tin oxide) material.

In above display panel, since the plurality of first electrodes 5 are transparent electrodes which may for example be formed by a transparent material, e.g., transparent ITO (Indium tin oxide), or may for example be other material which may form the transparent electrodes without influence on the pixel aperture ratio. The specific material of the plurality of first electrodes 5 may for example be chosen depending on practical conditions of the display panel.

As illustrated in FIG. 1 and FIG. 2, in an exemplary implementation of the disclosure, the display panel further comprises a common electrode 2.

For example, as illustrated in FIG. 1, in a condition that the common electrode 2 is arranged adjacent to (and for example illustrated to abut against) the array substrate 1, the pixel electrodes 7 are arranged away from the array substrate 1.

For example, as illustrated in FIG. 2, in a condition that the common electrode 2 is arranged away from the array substrate 1, the pixel electrodes 7 are arranged adjacent to (and for example illustrated to abut against) the array substrate 1.

More specifically, in a condition that above display panel is adapted to ADS (Advanced Super Dimension Switch) mode, as illustrated in FIG. 1, the common electrode 2 is arranged adjacent to (and for example illustrated to abut against) the array substrate 1, and the pixel electrodes 7 are arranged away from the array substrate 1. Then, in this display panel, the common electrode 2, a first insulating layer 3, the first metal layer, a second insulating layer 6 and the pixel electrodes 7 are formed sequentially on the array substrate 1. By way of example, as illustrated in FIG. 1, the common electrode is directly formed to abut against at least a portion of a surface at one side (e.g., upper surface as illustrated) of the array substrate 1, with various portions of the common electrode being spaced apart from one another; the first insulating layer 3 is either formed directly on a surface of the common electrode 2 facing away from the array substrate 1, or on portions of the upper surface of the array substrate 1 which portions are not covered by the common electrode 2; the first metal layer is formed directly on a portion of a surface of the first insulating layer 3 facing away from the array substrate 1, and as illustrated, at least a portion of the first metal layer is formed into the data lines 4; the second insulating layer 6 is formed on a surface of the first metal layer facing away from the array substrate 1, or on portions of the first insulating layer 3 at a side surface thereof which side surface is formed with the first metal layer thereon, which portions of the first insulating layer 3 are not covered by the first metal layer; and within the second insulating layer 6, there are the plurality of first electrodes 5 which are interposed in the second insulating layer 6 and spaced apart from one another, and there are also the pixel electrodes 7 formed directly on a surface of the second insulating layer 6 facing away from the array substrate 1. In other words, the second insulating layer 6 is provided between the layer in which the pixel electrodes 7 are located and the first metal layer, and covers the first metal layer, and the plurality of first electrodes 5 are provided in the second insulating layer 6 and between the first metal layer and the layer in which the pixel electrodes 7 are located, such that a shielding effect may be applied on the coupling capacitors created between the data lines 4 and the pixel electrodes 7, decreasing (or even eliminating) coupling capacitances between the data lines 4 and the pixel electrodes 7, in turn decreasing difference between pixel voltages of even rows and odd rows; and therefore, a horizontal trace-mura phenomenon, which is caused by the difference between pixel voltages of even rows and odd rows and macroscopically presented as both bright and dark stripes arranged alternately on the display panel, may further be mitigated so as to ensure an normal display effect of the display panel.

Therefore, the aforementioned display panel may decrease an occurrence of the bright and dark stripes arranged alternately so as to improve display quality.

Besides, as to a condition that above display panel is adapted to ADS mode, provided that the second insulating layer 6 effectively implements an isolating functionality at a slope angle position, a height of each of the plurality of first electrodes 5 in a vertical direction may for example be set within a size range of a thickness of the second insulating layer 6 at random.

And in a condition that above display panel is adapted to HADS (High Advanced Super Dimension Switch) mode, as illustrated in FIG. 2, the common electrode 2 is arranged away from the array substrate 1, and the pixel electrodes 7 are arranged adjacent to (and for example illustrated to abut against) the array substrate 1. Then, in this display panel, the pixel electrodes 7, a first insulating layer 3, the first metal layer, a second insulating layer 6 and the common electrode 2, are formed sequentially on the array substrate 1. By way of example, as illustrated in FIG. 2, the pixel electrodes 7 are directly formed to abut against at least a portion of a surface at one side (e.g., upper surface as illustrated) of the array substrate 1, and spaced apart from one another; the first insulating layer 3 is either formed directly on a surface of each of the pixel electrodes 7 facing away from the array substrate 1, or on portions of the array substrate 1 at a side surface thereof which side surface is formed with the pixel electrodes 7 thereon and faces away from the array substrate 1, which portions are not covered by the pixel electrodes 7, and there are the plurality of first electrodes 5 interposed within the first insulating layer 3 and spaced apart from one another; the first metal layer is formed directly on a portion of a surface of the first insulating layer 3 facing away from the array substrate 1, and as illustrated, at least a portion of the first metal layer is formed into the data lines 4; the second insulating layer 6 is formed on a surface of the first metal layer facing away from the array substrate 1, or on portions of the first insulating layer 3 at a side surface thereof which side surface is formed with the first metal layer thereon, which portions of the first insulating layer 3 are not covered by the first metal layer; and the common electrode 2 is in turn formed directly on a surface of the second insulating layer 6 facing away from the array substrate 1, with various portions of the common electrode 2 being spaced apart from one another. Moreover, for example, the plurality of first electrodes 5 are staggered from the pixel electrodes 7 in a vertical direction, i.e., orthogonal projections of the plurality of first electrodes 5 in the vertical direction fail to overlap with the pixel electrodes 7. In other words, the first insulating layer 3 is provided between the layer in which the pixel electrodes 7 are located and the first metal layer, and covers the first metal layer, and the plurality of first electrodes 5 are provided in the first insulating layer 3 and between the first metal layer and the layer in which the pixel electrodes 7 are located, such that a shielding effect may be applied on the coupling capacitors created between the data lines 4 and the pixel electrodes 7, decreasing (or even eliminating) coupling capacitances between the data lines 4 and the pixel electrodes 7, in turn decreasing the difference between pixel voltages of even rows and odd rows; and therefore, a horizontal trace-mura phenomenon, which is caused by the difference between pixel voltages of even rows and odd rows and macroscopically presented as both bright and dark stripes arranged alternately on the display panel, may further be mitigated so as to ensure an normal display effect of the display panel.

Therefore, in the condition that above display panel is adapted to HADS mode, the aforementioned display panel may decrease an occurrence of the bright and dark stripes arranged alternately so as to improve display quality.

Besides, as to a condition that above display panel is adapted to HADS mode, provided that the first insulating layer 3 effectively implements an isolating functionality at a slope angle position, a height of each of the plurality of first electrodes 5 in a vertical direction may for example be set within a size range of a thickness of the first insulating layer 3 at random.

Based on each of above display panels, in order to avoid any influence on display pixels and to avoid an increase in power consumption of the display panel, specifically, the plurality of first electrodes 5 may for example be connected with the common electrode 2 through via-holes.

By way of example, as illustrated in FIG. 3 which is on the basis of FIG. 1, the plurality of first electrodes 5 may be connected with the common electrode 2 through respective via-hole(s) at least partially formed within the second insulating layer 6 and passing through the first insulating layer 3.

Or otherwise, for example, as illustrated in FIG. 4 which is on the basis of FIG. 2, the plurality of first electrodes 5 may be connected with the common electrode 2 through respective via-hole(s) at least partially be formed within the first insulating layer 3 and passing through the second insulating layer 6.

In each of above display panels, the plurality of first electrodes 5 and the common electrode 2 are electrically connected with each other through respective via-holes, then a same principal common voltage (abbreviated as ‘com’ voltage) of the display panel is applied to both the plurality of first electrodes 5 and the common electrode 2, simultaneously. Although there are the plurality of first electrodes existing between the first metal layer and the layer in which the pixel electrodes 7 are located, due to the existence of the same principal ‘com’ voltage of the display panel, then display of the pixels may not be influenced, so as to ensure display effect/quality of the display panel. In addition, since the same principal ‘com’ voltage of the display panel is applied to both the plurality of first electrodes 5 and the common electrode 2, it is unnecessary to apply an additional external voltage to the plurality of first electrodes; therefore 5, although the plurality of first electrodes 5 are additionally provided between the first metal layer and the layer in which the pixel electrodes 7 are located, there will be no increase in power consumption of the display panel.

Based on the fact that the aforementioned display panel may decrease the occurrence of the bright and dark stripes arranged alternately and thus improve display quality, in order to further decrease the coupling capacitances created between the data lines 4 and the pixel electrodes 7, according to an exemplary embodiment, at least a portion of an orthogonal projection of each of the plurality of first electrodes 5 on the first metal layer does not overlap with respective one of the data lines 4.

In above display panel, as illustrated, by way of example, in a condition that the orthogonal projection of each of the plurality of first electrodes 5 on the first metal layer may in no way overlap with the data lines 4, then, the coupling capacitances created between the data lines 4 and the pixel electrodes 7 are least influenced by adding the plurality of first electrodes 5 between the first metal layer and the layer in which the pixel electrodes 7 are located, so as to decrease minimally the coupling capacitances between the data lines 4 and the pixel electrodes 7; and in a condition that a relatively small portion of the orthogonal projection of each of the plurality of first electrodes 5 on the first metal layer overlaps with the data lines, then, the coupling capacitances created between the data lines 4 and the pixel electrodes 7 may be less influenced by adding the plurality of first electrodes 5 between the first metal layer and the layer in which the pixel electrodes 7 are located, so as to decrease at least a relatively small portion of the coupling capacitances between the data lines 4 and the pixel electrodes 7.

In an alternative embodiment, in a condition that a relatively large portion of the orthogonal projection of each of the plurality of first electrodes 5 on the first metal layer overlaps with the data lines, then, the coupling capacitances created between the data lines 4 and the pixel electrodes 7 may be more influenced by adding the plurality of first electrodes 5 between the first metal layer and the layer in which the pixel electrodes 7 are located, so as to decrease at least a relatively large portion of the coupling capacitances between the data lines 4 and the pixel electrodes 7. Based on this fact, in a further embodiment of the disclosure, the orthogonal projection of each of the plurality of first electrodes 5 on the first metal layer may for example overlap with the data lines 4 completely, then, the coupling capacitances created between the data lines 4 and the pixel electrodes 7 are maximally influenced by adding the plurality of first electrodes 5 between the first metal layer and the layer in which the pixel electrodes 7 are located, so as to decrease maximally the coupling capacitances between the data lines 4 and the pixel electrodes 7.

As to an extent concerning an overlapping degree of the orthogonal projection of each of the plurality of first electrodes 5 on the first metal layer overlapping with the data lines, within the display panel, the extent may be chosen specifically, by considering comprehensively a practical condition of the display panel.

Based on the fact that the aforementioned display panel may further decrease the coupling capacitances created between the data lines 4 and the pixel electrodes 7, in order to decrease an influence on the principal ‘com’ voltage of the display panel applied by the capacitances between the data lines 4 and the common electrode 2, specifically, the plurality of first electrodes 5 are for example individually and electrically connected to an external common voltage.

In above display panel, in a condition that the orthogonal projection of each of the plurality of first electrodes 5 on the first metal layer may in no way overlap with the data lines 4, then, the influence on the principal ‘com’ voltage of the display panel applied by the capacitances created between the data lines 4 and the common electrode 2 is minimized; and in order to decrease the coupling capacitances between the data lines 4 and the pixel electrodes 7 to a relatively large extent, and also to decrease the influence on the principal ‘com’ voltage of the display panel applied by the capacitances between the data lines 4 and the common electrode 2 simultaneously, e.g., the plurality of first electrodes 5 may for example be individually and electrically connected to an external common voltage, then, the voltage of each of the plurality of first electrodes 5 is electrically separated/isolated from the principal ‘com’ voltage of the display panel, and thus the influence on the principal ‘com’ voltage of the display panel applied by the capacitances between the data lines 4 and the common electrode 2 may be relatively small.

As illustrated in FIG. 2, based on the fact that the aforementioned display panel may decrease the occurrence of the bright and dark stripes arranged alternately and thus improve display quality, according to an embodiment of the disclosure, in a condition that the pixel electrodes 7 are arranged adjacent to (and for example illustrated to abut against) the array substrate 1, then, in the display panel, since an orthogonal projection of the plurality of first electrodes 5 on the layer in which the pixel electrodes 7 are located does not overlap with the pixel electrodes 7.

In a condition that above display panel is adapted to HADS (High Advanced Super Dimension Switch) mode as illustrated in FIG. 2, i.e., the common electrode 2 is located away from the array substrate 1, and the pixel electrodes 7 are arranged adjacent to (and for example illustrated to abut against) the array substrate 1, then, in such a display panel, an orthogonal projection of the plurality of first electrodes 5 on the layer in which the pixel electrodes 7 are located does not overlap with the pixel electrodes 7, so as to avoid any influence on a pixel electric field applied by adding the first electrodes 5, and further to avoid any difference created between an edge display region and a central display region of each of the pixels.

Based on the fact that above display panel may avoid the influence on the pixel electric field applied by adding the first electrodes, in order to further decrease the influence applied by adding the first electrodes 5, specifically, an orthogonal projection of the plurality of first electrodes 5 on the layer in which the common electrode 2 is located at least partially overlaps with the common electrode.

In above display panel, the an orthogonal projection of the plurality of first electrodes 5 on the layer in which the common electrode 2 is located at least partially overlaps with the common electrode, then, the plurality of first electrodes may not be arranged beyond locations of edges of the common electrode 2, so as to decrease an influence on the pixel electric field at the locations of edges which influence is applied by the first electrodes 5, and in turn to avoid any difference created between the edge display region and the central display region of each of the pixels whenever possible.

As illustrated in FIG. 1, according to an exemplary embodiment of the disclosure, the display panel may for example further comprise an alignment substrate 10 provided opposite to the array substrate 1, with a black matrix 9 being formed on the alignment substrate 10, wherein in a condition that the pixel electrodes 7 are provided away from the array substrate, an orthogonal projection of the plurality of first electrodes 5 on a layer in which the black matrix 9 is located falls within an extent of the black matrix 9.

In a condition that above display panel is adapted to ADS (Advanced Super Dimension Switch) mode as illustrated in FIG. 2, i.e., the common electrode 2 is arranged adjacent to (and for example illustrated to abut against) the array substrate 1, and the pixel electrodes 7 are arranged away from the array substrate 1, then, in such a display panel, there is a liquid crystal layer 8 provided between the array substrate 1 and the alignment substrate 10 opposite to each other, and since the orthogonal projection of the plurality of first electrodes 5 on the layer in which the black matrix 9 is located falls within an extent of the black matrix 9, i.e., the plurality of first electrodes may not be arranged beyond edges of the black matrix 9, then, in a condition that the plurality of first electrodes 5 influence display effect of edge pixels, any influenced regions may be shielded by the black matrix 9.

And in a condition that above display panel is adapted to HADS (High Advanced Super Dimension Switch) mode as illustrated in FIG. 2, i.e., the common electrode 2 is located away from the array substrate 1, and the pixel electrodes 7 are arranged adjacent to (and for example illustrated to abut against) the array substrate 1, then, in such a display panel, there is a liquid crystal layer 8 provided between the array substrate 1 and the alignment substrate 10 opposite to each other. In the HADS mode as illustrated in FIG. 2, as mentioned above, the orthogonal projection of the plurality of first electrodes 5 on the layer in which the pixel electrodes 7 are located does not overlap with the pixel electrodes, so as to avoid any influence on a pixel electric field applied by adding the first electrodes 5, and further to avoid any difference created between an edge display region and a central display region of each of the pixels whenever possible. Therefore, the orthogonal projection of the plurality of first electrodes 5 on the layer in which the black matrix 9 is located as illustrated in FIG. 2 may not necessarily fall completely within the extent of the black matrix 9, i.e., the plurality of first electrodes 5 may for example be arranged partially beyond the edges of the black matrix.

In addition, in another aspect of the embodiments of the disclosure, there is further provided a display device, comprising the display panel according to any one item of above technical solutions, and a housing receiving the display panel.

The solutions of above embodiments of the disclosure have following beneficial technical effects:

In embodiments of the disclosure, the shielding effect may be applied on the coupling capacitors created between the data lines and the pixel electrodes, decreasing (or even eliminating) the coupling capacitances between the data lines and the pixel electrodes, in turn decreasing (or even eliminating) an influence on pixel voltages applied by the coupling capacitors created between the data lines and the pixel electrodes, and resulting in a decreased difference between pixel voltages of even rows and odd rows; and therefore, a horizontal trace-mura phenomenon, which is caused by the difference between pixel voltages of even rows and odd rows and macroscopically presented as both bright and dark stripes arranged alternately on the display panel, may further be mitigated so as to ensure an normal display effect of the display panel. Since the display panel may decrease an occurrence of the bright and dark stripes arranged alternately so as to improve display quality, then, the display device comprising the display panel may also has a relatively high product yield.

It should be appreciated for those skilled in this art that the above embodiments are intended to be illustrated, and not restrictive. For example, many modifications may be made to the above embodiments by those skilled in this art, and various features described in different embodiments may be freely combined with each other without conflicting in configuration or principle.

Although the disclosure is described in view of the attached drawings, the embodiments disclosed in the drawings are only intended to illustrate the preferable embodiment of the present disclosure exemplarily, and should not be deemed as a restriction thereof.

Although several exemplary embodiments of the general concept of the present disclosure have been shown and described, it would be appreciated by those skilled in the art that various changes or modifications may be made in these embodiments without departing from the principles and spirit of the disclosure and lie within the scope of present application, which scope is defined in the claims and their equivalents.

As used herein, an element recited in the singular and proceeded with the word “a” or “an” should be understood as not excluding plural of said elements or steps, unless such exclusion is explicitly stated. Furthermore, references to “one embodiment” of the present disclosure are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

What is claimed is:

1. A display panel, comprising:
an array substrate; and
a first metal layer and pixel electrodes, both being formed on the array substrate, the first metal layer forming data lines,
wherein the display panel further comprises a plurality of first electrodes which are arranged to be spaced apart from one another and provided between the first metal layer and a layer in which the pixel electrodes are located.

2. The display panel according to claim 1, wherein the plurality of first electrode are transparent electrodes.

3. The display panel according to claim 2, wherein the transparent electrodes are formed by transparent ITO material.

4. The display panel according to claim 1, further comprising a common electrode,
wherein in response to the common electrode being arranged adjacent to and abutting against the array substrate, the pixel electrodes are arranged away from the array substrate.

5. The display panel according to claim 1, further comprising a common electrode,
wherein in response to the common electrode being arranged away from the array substrate, the pixel electrodes are arranged adjacent to and abutting against the array substrate.

6. The display panel according to claim 4, wherein the plurality of first electrodes are connected with the common electrode through via-holes.

7. The display panel according to claim 5, wherein the plurality of first electrodes are connected with the common electrode through via-holes.

8. The display panel according to claim 4, wherein at least a portion of an orthogonal projection of each of the plurality of first electrodes on the first metal layer does not overlap with respective one of the data lines.

9. The display panel according to claim 5, wherein at least a portion of an orthogonal projection of each of the plurality of first electrodes on the first metal layer does not overlap with respective one of the data lines.

10. The display panel according to claim 8, wherein the plurality of first electrodes are electrically connected to an external common voltage.

11. The display panel according to claim 9, wherein the plurality of first electrodes are electrically connected to an external common voltage.

12. The display panel according to claim 9, wherein an orthogonal projection of the plurality of first electrodes on the layer in which the pixel electrodes are located does not overlap with the pixel electrodes.

13. The display panel according to claim 12, wherein an orthogonal projection of the plurality of first electrodes on the layer in which the common electrode is located at least partially overlaps with the common electrode.

14. The display panel according to claim 8, further comprising an alignment substrate provided opposite to the array substrate, with a black matrix being formed on the alignment substrate, wherein in response to the pixel electrodes being provided away from the array substrate, an orthogonal projection of the plurality of first electrodes on a layer in which the black matrix is located falls within an extent of the black matrix.

15. A display device, comprising:
the display panel according to claim 1; and
a housing receiving the display panel.
